(19) United States
(12) Patent Application Publication
(10) Pub. No.: US 2023/0128951 A1
(43) Pub. Date: Apr. 27, 2023

(54) HEAT EXCHANGER FOR POWER ELECTRONICS

(71) Applicant: Carrier Corporation, Palm Beach Gardens, FL (US)

(72) Inventors: Arindom Joardar, Jamesville, NY (US); Lokanath Mohanta, Liverpool, NY (US); Konstantin Borisov, Avon, CT (US); Ismail Agirman, Southington, CT (US)

(21) Appl. No.: 18/048,265

(22) Filed: Oct. 20, 2022

Related U.S. Application Data
(60) Provisional application No. 63/272,359, filed on Oct. 27, 2021.

(51) Int. Cl. F24F 1/24; F24F 13/30; F24F 13/22

(52) U.S. Cl. CPC F24F 1/24; F24F 13/30; F24F 13/222

(57) ABSTRACT

A power electronics assembly includes one or more power electronics devices, and a heat exchanger to which the one or more power electronics devices are mounted. The heat exchanger includes one or more fluid pathways extending through the heat exchanger to transfer thermal energy from the one or more power electronics devices into a flow of fluid passing through the one or more fluid pathways. The flow of fluid is a flow of liquid refrigerant diverted from a condenser of a heating, ventilation, and air conditioning (HVAC) system. The one or more power electronics devices includes at least one power electronics device located on each opposing lateral side of the heat exchanger.

### CROSS-REFERENCE TO RELATED APPLICATIONS

This application claims the benefit of U.S. Provisional Patent Application No. 63/272,359 filed Oct. 27, 2021, the disclosure of which is incorporated herein by reference in its entirety.

### BACKGROUND

Exemplary embodiments pertain to the art of heat exchangers, and more particularly to heat exchangers for cooling power electronics.

Power electronics devices such as motor drives generate waste heat during operation of the device. Additionally, when the power electronics devices heat up the operational efficiency of the devices can degrade adding to the amount of heat generated. When utilized in a refrigeration system to drive, for example, a compressor of the refrigeration system, effective thermal integration of these devices can be important aspect to the system's overall efficiency and reliability. Consequently, a goal of the system integrator is to maintain these components within a range of operating temperatures which will maximize the system efficiency. Accordingly, there remains a need in the art for heat exchangers configured to closely integrate with power electronic devices which can maintain optimal temperatures for these components under a variety of load conditions.

### BRIEF DESCRIPTION

In one embodiment, a power electronics assembly includes one or more power electronics devices, and a heat exchanger to which the one or more power electronics devices are mounted. The heat exchanger includes one or more fluid pathways extending through the heat exchanger to transfer thermal energy from the one or more power electronics devices into a flow of fluid passing through the one or more fluid pathways. The flow of fluid is a flow of liquid refrigerant diverted from a condenser of a heating, ventilation, and air conditioning (HVAC) system. The one or more power electronics devices includes at least one power electronics device located on each opposing lateral side of the heat exchanger.

Additionally or alternatively, in this or other embodiments the heat exchanger includes multiple columns of the fluid pathways arranged between the opposing lateral sides of the heat exchanger.

Additionally or alternatively, in this or other embodiments each column of the multiple columns of fluid pathways defines an independent fluid circuit.

Additionally or alternatively, in this or other embodiments each column of fluid pathways is configured to cool the at least one power electronics device at the lateral side of the heat exchanger nearest each column.

Additionally or alternatively, in this or other embodiments the one or more fluid pathways include one or more fins extending inwardly from a pathway inner wall.

Additionally or alternatively, in this or other embodiments each fin of the one or more fins has a fin height in the range of 0.2 millimeters to 0.5 millimeters.

Additionally or alternatively, in this or other embodiments one or more condensate drainage passages are formed in an exterior surface of the heat exchanger configured to drain condensate formed on one or more of the one or more power electronics devices or on the heat exchanger.

Additionally or alternatively, in this or other embodiments the one or more condensate drainage passages have a T-shaped cross-section.

Additionally or alternatively, in this or other embodiments the one or more fluid pathways extend off of horizontal along a fluid pathway length.

In another embodiment, a method of cooling one or more power electronics devices includes securing the one or more power electronics devices to a heat exchanger. The heat exchanger includes one or more fluid pathways. A flow of fluid is circulated through one or more fluid pathways to transfer thermal energy from the one or more power electronics to the flow of fluid passing through the one or more fluid pathways. The flow of fluid is a flow of liquid refrigerant diverted from a condenser of a heating, ventilation, and air conditioning (HVAC) system. At least one power electronics device is located on each opposing lateral side of the heat exchanger.

Additionally or alternatively, in this or other embodiments the heat exchanger includes multiple columns of the fluid pathways arranged between the opposing lateral sides of the heat exchanger.

Additionally or alternatively, in this or other embodiments a first flow of fluid is circulated through a first column of fluid pathways, and a second flow of fluid is circulated through a second column of fluid pathways.

Additionally or alternatively, in this or other embodiments a first power electronics device located at a first lateral side of the heat exchanger is cooled via the first flow of fluid and a second power electronics device located at a second lateral side of the heat exchanger is cooled via the second flow of fluid.

Additionally or alternatively, in this or other embodiments the one or more fluid pathways include one or more fins extending inwardly from a pathway inner wall.

Additionally or alternatively, in this or other embodiments each fin of the one or more fins has a fin height in the range of 0.2 millimeters to 0.5 millimeters.

Additionally or alternatively, in this or other embodiments condensate formed on one or more of the one or more power electronics devices or on the heat exchanger is drained via one or more condensate drainage passages formed in an exterior surface of the heat exchanger.

Additionally or alternatively, in this or other embodiments the one or more condensate drainage passages have a T-shaped cross-section.

Additionally or alternatively, in this or other embodiments the one or more fluid pathways extend off or horizontal along a fluid pathway length.

### BRIEF DESCRIPTION OF THE DRAWINGS

The following descriptions should not be considered limiting in any way. With reference to the accompanying drawings, like elements are numbered alike:

FIG. 1 is an illustration of an embodiment of an exemplary power electronics assembly;

FIG. 2 is an illustration of an embodiment of an exemplary heating, ventilation, and air conditioning (HVAC) system;

FIG. 3 is an illustration of an embodiment of a heat exchanger of an exemplary power electronics assembly;

FIG. 4 is an illustration of an embodiment of an exemplary heat exchanger having multiple fluid pathway columns;

FIG. 5 is an illustration of another embodiment of an exemplary heat exchanger having multiple fluid pathway columns;

FIG. 6 is a cross-sectional view of an embodiment of an exemplary fluid pathway having internal fins;

FIG. 7 is a perspective view of an exemplary fin structure;

FIG. 8 is an illustration of an exemplary helix angle of a fin of a fluid pathway;

FIG. 9 is a cross-sectional view of an exemplary heat exchanger having condensate drainage passages; and

FIG. 10 is a view of an exemplary heat exchanger showing an orientation of fluid pathways.

### DETAILED DESCRIPTION

A detailed description of one or more embodiments of the disclosed apparatus and method are presented herein by way of exemplification and not limitation with reference to the Figures.

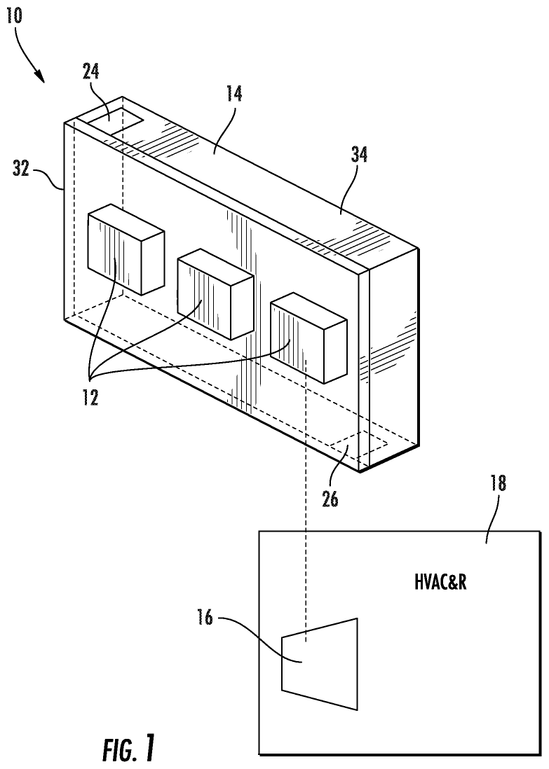

Illustrated in FIG. 1 is an embodiment of a power electronics assembly 10. The power electronics assembly 10 includes one or more power electronics devices 12 mounted to a heat exchanger 14 utilized to reject and dissipate thermal energy generated by the power electronics devices 12 during operation. In some embodiments, the power electronics devices 12 include a variable frequency drive (VFD) operably connected to a compressor 16 of a heating, ventilation, and air conditioning (HVAC) system 18.

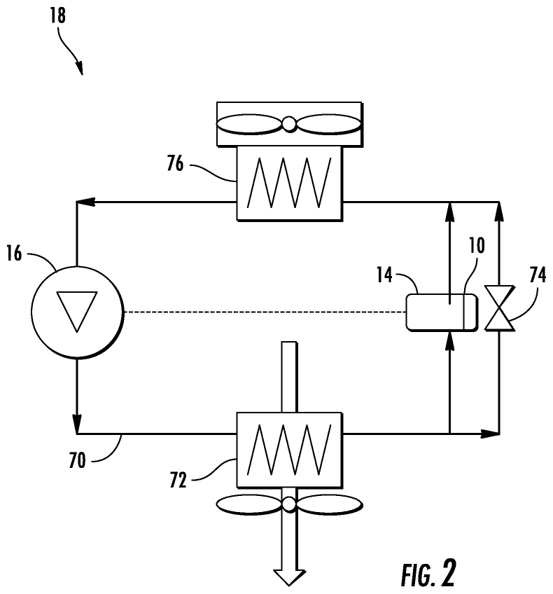

Referring to FIG. 2, the HVAC system 18 includes, for example, a vapor compression circuit 70 including the compressor 16, a condenser 72, an expansion device 74 and an evaporator 76 arranged in series and having a volume of refrigerant flowing therethrough. The power electronics assembly 10 is connected to the vapor compression circuit 70 such that a portion of the flow of liquid refrigerant exiting the condenser 72 is diverted through the heat exchanger 14, bypassing the expansion device 74 and is directed from the heat exchanger 14 to the evaporator 76. The liquid refrigerant from the condenser 72 absorbs thermal energy generated by the power electronics devices 12. This thermal energy generated by the power electronics devices 12 may cause the refrigerant passing through the heat exchanger 14 to boil, changing phase of the refrigerant from liquid to vapor inside the heat exchanger 14.

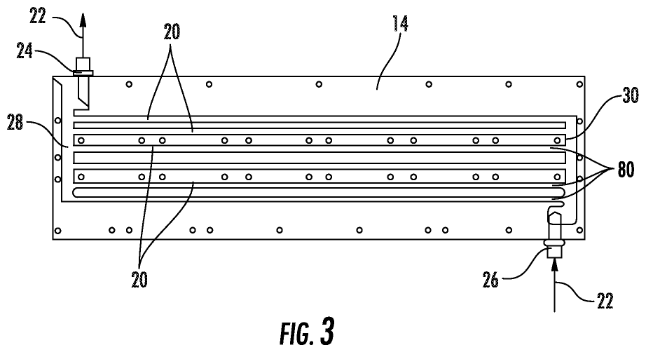

Referring now to FIG. 3, the exemplary heat exchanger 14 is illustrated in more detail. As shown, the heat exchanger 14 includes a plurality of enclosed fluid pathways 20 enabling a flow of fluid 22 such as, for example, refrigerant, glycol, or water to flow therein. The fluid pathways 20 extend between a heat exchanger inlet 26 through which the flow of fluid 22 enters the heat exchanger 14, and a heat exchanger outlet 24 through which the flow of fluid 22 exits the heat exchanger 14. The heat exchanger inlet 26 is connected to the fluid pathways 20 via an inlet manifold 30 to distribute the flow of fluid 22 to the fluid pathways 20, and similarly the heat exchanger outlet 24 is connected to the fluid pathways 20 via an outlet manifold 28. Immediately downstream of the inlet manifold 30, orifices 80 of different diameters, increasing with increasing distance from the heat exchanger inlet 26 are provided to distribute the flow of fluid 22 from the inlet manifold 30 equally among all of the fluid pathways 20. The enhancement features described in the following text will be in the fluid pathways 20 downstream of the respective orifices 80.

In some embodiments, the heat exchanger 14 is formed from a metal material, such as aluminum, aluminum alloy, steel, steel alloy, copper, copper alloy, or the like, and referring again to FIG. 1, may be formed from two or more plates 32, 34 abutting one another along a side and joined using any suitable means such as brazing, welding, clamping, compressing, bolting, and the like. The plates 32, 34 may each include a portion of the fluid pathways 20, the inlet manifold 30, the outlet manifold 28, the heat exchanger inlet 26 and/or the heat exchanger outlet 24 formed therein. The mating surfaces of the plates 32, 34 can be configured to correspond to one another, e.g., to fit together and seal the fluid circuit therebetween. The mating surfaces of the plates 32, 34 can include precision surfaces formed from a process having highly accurate and precise dimensional control, such as through computer numerical control (CNC) machining process and/or net shape, or near net shape manufacturing process. Optionally or additionally, a sealing material can be disposed between the plates 32, 34 to aide in preventing leakage from the fluid circuit.

In operation, the flow of fluid 22, liquid refrigerant from the condenser 72, enters the heat exchanger 14 at the heat exchanger inlet 26 and is distributed to the fluid pathways 20 via the inlet manifold 30. The heat exchanger 14 conducts thermal energy from the power electronics devices 12 and thermal energy is exchanged with the flow of fluid 22 flowing through the fluid pathways 20, resulting in cooling of the power electronics devices 12. The vapor flow of fluid 22 is then collected at the outlet manifold 28 and exits the heat exchanger 14 at the heat exchanger outlet 24. The flow of fluid 22 provided to the heat exchanger 14 is diverted from the condenser 72 and in some embodiments enters the heat exchanger 14 in a liquid phase with 0% vapor quality or up to 20% vapor quality. The presently disclosed heat exchanger 14 may be operated to ensure the vapor quality of the flow of fluid 22 exiting the heat exchanger 14 has a vapor quality of from about 25% to about 80%, or in another embodiment from about 40% to about 60%, or in yet another embodiment from about 45% to about 55%, or about 50%. The vapor quality change happens as the heat from power electronics devices 12 is absorbed by the flow and used for phase change of the liquid refrigerant to vapor while travelling from the heat exchanger inlet 26 to the heat exchanger outlet 24. In the present disclosure, features of the heat exchanger 14 are disclosed which improve performance of the heat exchanger 14, many of which are features to improve boiling performance of the flow of fluid 22, the refrigerant from the condenser 72.

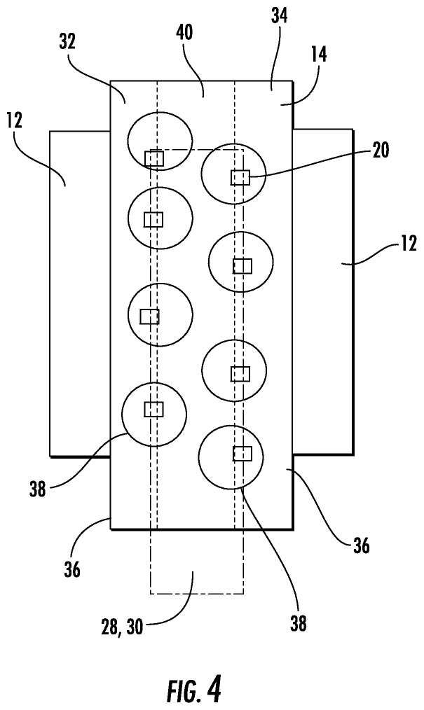

Referring now to FIG. 4, in some embodiments, power electronics devices 12 are installed to both lateral sides 36 of the heat exchanger 14. To accomplish cooling of the power electronics devices 12 in such configurations, the heat exchanger 14 may have one, or two or more pathway columns 38 of fluid pathways 20 arranged between the lateral sides 36. This may increase the flow of fluid 22 through the heat exchanger 14, and enable the fluid 22 to be in closer proximity to the respective power electronics devices 12 (as compared to a single column positioned in the center of the lateral sides 36). In such configurations, the heat exchanger 14 may have an additional middle plate 40 between the plates 32, 34 in which a portion of each pathway column 38 is formed. The columns can be adjacent to each other to increase thermal mass of the heat exchanger 14 or in a staggered arrangement to reduce the thermal mass hence weight of the heat exchanger 14.

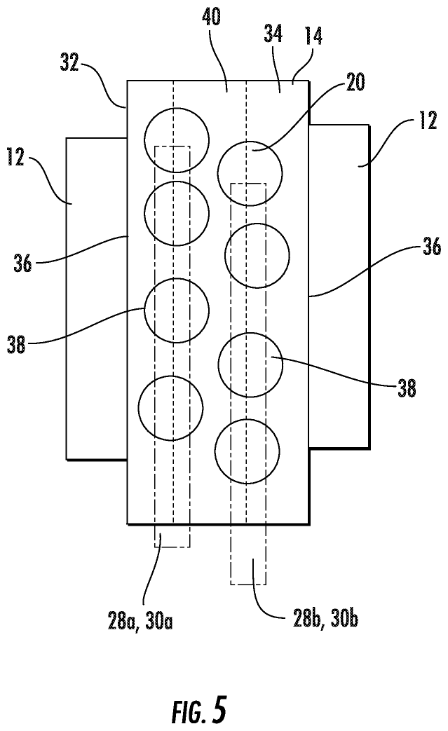

In some embodiments, such as shown in FIG. 4, the two pathway columns 38 share a common inlet manifold 30 and a common outlet manifold 28. In other embodiments, such as illustrated in FIG. 5, a first pathway column 38a utilizes a first inlet manifold 30a and a first outlet manifold 28a having a first flow of fluid 22a defining a first circuit. Similarly, a second pathway column 38b utilizes a second inlet manifold 30b and a second outlet manifold 28b having a second flow of fluid 22b defining a second circuit. Having separate first and second circuits in the heat exchanger 14 allows for the flow of each fluid 22a, 22b to be tuned separately to meet the cooling requirements for the power electronics devices at each lateral side 36 of the heat exchanger 14. For example, in some embodiments, the fluid pathways 20a of the first pathway column 38a may be the same configuration as the fluid pathways 20b of the second pathway column 38b, or the configurations may be different having, for example, different pathway sizes, internal or external features, different materials, or the like. Further, a number of pathways in each of the pathway columns 38a, 38b may differ and/or a different fluid may be circulated in each pathway column 38a, 38b.

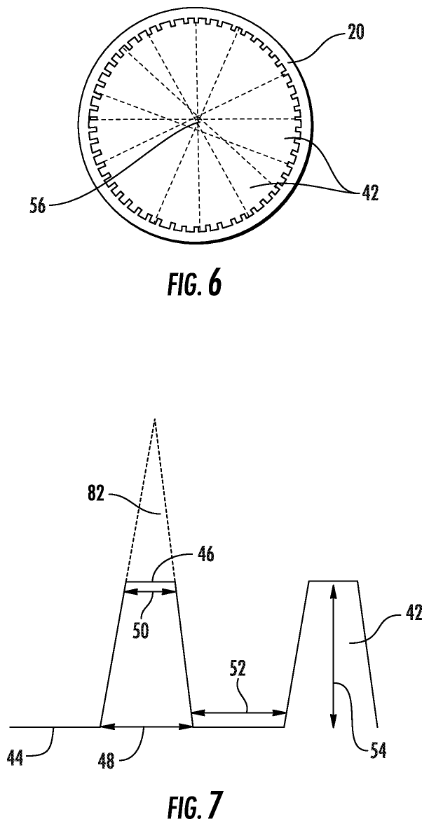

Referring now to FIGS. 6 and 7, in some embodiments, the fluid pathways 20 include a plurality of fins 42 extending radially inwardly from a pathway inner wall 44 to a fin tip 46. Each fin 42 has a circumferential base width 48 and a circumferential tip width 50, as well as a circumferential fin spacing 52 between adjacent fins 42, defined at the pathway inner wall 44. In some embodiments, the tip width 50 is in the range of 0.01 millimeters to 0.1 millimeters. Additionally, the fin spacing 52 may be in the range of 0.05 millimeters and 0.5 millimeters. The fins 42 further each have a fin height 54 from the pathway inner wall 44 to the fin tip 46. The fin height 54 may be in a range of, for example, 0.2 millimeters to 0.5 millimeters, depending on a pathway hydraulic diameter, which in some embodiments is in the range of 5 millimeters to 20 millimeters. In some embodiments, a number of fins 42 in a fluid pathway 20 is in the range of 30-80 fins 42. The plurality of fins 42 may extend substantially linearly parallel to a pathway central axis 56 or alternatively may extend helically about the pathway central axis 56 along a length of the pathway 20, at a helix angle 82 in the range of 10 degrees to 30 degrees, such as shown in FIG. 8. Additionally, referring again to FIG. 7, the fins 42 have an apex angle 84 between adjacent sidewalls of the fins 42, which may be in the range of 20 degrees to 60 degrees.

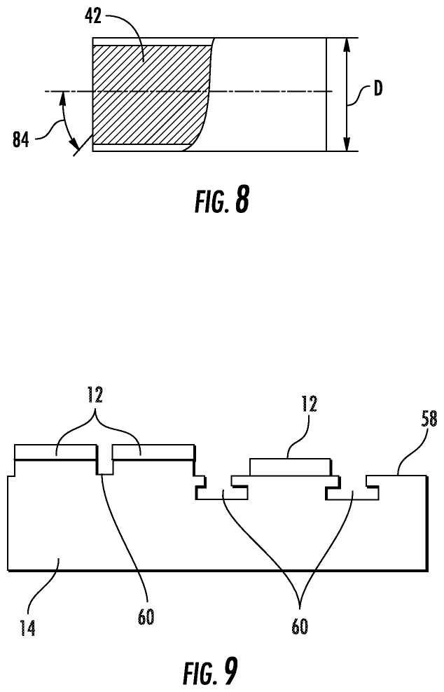

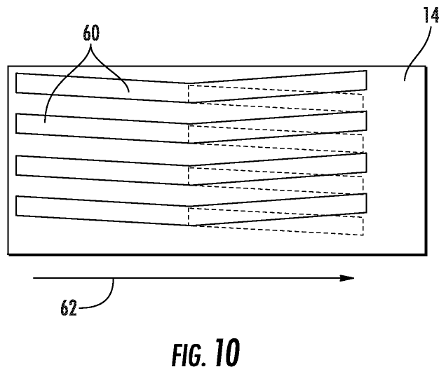

Referring now to FIG. 9, a heat exchanger outer wall 58 may include condensate drainage passages 60 located between adjacent power electronics devices 12. During operation, condensate may form on the cooler walls of the heat exchanger outer wall 58. The condensate drainage passages 60, when present, collect the condensate and drain the condensate away from the power electronics devices 12. In some embodiments, the condensate drainage passages 60 have a T-shaped cross-section to contain the condensate and drain the condensate away from the power electronics devices. Referring now to FIG. 10, the fluid pathways 20 may extend in a direction off of horizontal along the fluid pathway length. This promotes drainage of the flow of fluid 22 from the heat exchanger 14 via gravity when the HVAC system 18 is deactivated. In some embodiments, such as shown, the fluid pathways 20 are chevron-shaped along the fluid pathway length, while in other embodiments the fluid pathways 20 are simply inclined in one direction relative to horizontal. Other configurations of fluid pathways 20 are contemplated within the scope of the present disclosure.

The configurations of heat exchangers 14 and power electronics assemblies 10 disclosed herein increase heat transfer area in the fluid pathways 20 and promote convective evaporation and boiling of the flow of fluid 22 in the heat exchanger 14 to improve heat transfer rate of the heat exchanger 14. Further, the configurations reduce a volume of heat exchanger 14 for cooling the power electronics devices 12.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A power electronics assembly, comprising:
one or more power electronics devices; and
a heat exchanger to which the one or more power electronics devices are mounted, the heat exchanger comprising:
one or more fluid pathways extending through the heat exchanger to transfer thermal energy from the one or more power electronics devices into a flow of fluid passing through the one or more fluid pathways;
wherein the flow of fluid is a flow of liquid refrigerant diverted from a condenser of a heating, ventilation, and air conditioning (HVAC) system;
wherein the one or more power electronics devices includes at least one power electronics device located on each opposing lateral side of the heat exchanger.

2. The power electronics assembly of claim 1, wherein the heat exchanger includes multiple columns of the fluid pathways arranged between the opposing lateral sides of the heat exchanger.

3. The power electronics assembly of claim 2, wherein each column of the multiple columns of fluid pathways defines an independent fluid circuit.

4. The power electronics assembly of claim 2, wherein each column of fluid pathways is configured to cool the at least one power electronics device at the lateral side of the heat exchanger nearest each column.

5. The power electronics assembly of claim 1, wherein the one or more fluid pathways include one or more fins extending inwardly from a pathway inner wall.

6. The power electronics assembly of claim 5, wherein each fin of the one or more fins has a fin height in the range of 0.2 millimeters to 0.5 millimeters.

7. The power electronics assembly of claim 1, further comprising one or more condensate drainage passages formed in an exterior surface of the heat exchanger configured to drain condensate formed on one or more of the one or more power electronics devices or on the heat exchanger.

8. The power electronics assembly of claim 7, wherein the one or more condensate drainage passages have a T-shaped cross-section.

9. The power electronics assembly of claim 1, wherein the one or more fluid pathways extend off of horizontal along a fluid pathway length.

10. A method of cooling one or more power electronics devices, comprising:
securing the one or more power electronics devices to a heat exchanger, the heat exchanger comprising one or more fluid pathways;
circulating a flow of fluid through one or more fluid pathways to transfer thermal energy from the one or more power electronics to the flow of fluid passing through the one or more fluid pathways;
wherein the flow of fluid is a flow of liquid refrigerant diverted from a condenser of a heating, ventilation, and air conditioning (HVAC) system;
wherein at least one power electronics device is located on each opposing lateral side of the heat exchanger.

11. The method of claim 10, wherein the heat exchanger includes multiple columns of the fluid pathways arranged between the opposing lateral sides of the heat exchanger.

12. The method of claim 11, further comprising:
circulating a first flow of fluid through a first column of fluid pathways; and
circulating a second flow of fluid through a second column of fluid pathways.

13. The method of claim 11, further comprising:
cooling a first power electronics device disposed at a first lateral side of the heat exchanger via the first flow of fluid; and
cooling a second power electronics device disposed at a second lateral side of the heat exchanger via the second flow of fluid.

14. The method of claim 10, wherein the one or more fluid pathways include one or more fins extending inwardly from a pathway inner wall.

15. The method of claim 14, wherein each fin of the one or more fins has a fin height in the range of 0.2 millimeters to 0.5 millimeters.

16. The method of claim 10, further comprising draining condensate formed on one or more of the one or more power electronics devices or on the heat exchanger via one or more condensate drainage passages formed in an exterior surface of the heat exchanger.

17. The method of claim 16, wherein the one or more condensate drainage passages have a T-shaped cross-section.

18. The method of claim 10, wherein the one or more fluid pathways extend off or horizontal along a fluid pathway length.
